(19) United States
(12) Patent Application Publication
(10) Pub. No.: US 2012/0139541 A1
(43) Pub. Date: Jun. 7, 2012

(54) DETERMINATION OF LOCAL SAR IN VIVO AND ELECTRICAL CONDUCTIVITY MAPPING

(75) Inventors: Steffen Weiss, Hamburg (DE); Ulrich Katscher, Hamburg (DE); Peter Vernickel, Hamburg (DE); Tobias Ratko Voigt, Hamburg (DE); Christian Findeklee, Hamburg (DE)

(73) Assignee: KONINKLIJKE PHILIPS ELECTRONICS N.V., EINDHOVEN (NL)

(21) Appl. No.: 12/933,894

(22) PCT Filed: Mar. 25, 2009
(86) PCT No.: PCT/IB09/51231

§ 371 Date: Oct. 15, 2010

(30) Foreign Application Priority Data
Mar. 26, 2008 (EP) 08153293.9

(51) Int. Cl. G01R 33/44

(52) U.S. Cl. 324/318

(57) ABSTRACT

A magnetic resonance imaging apparatus produces calculations of local specific energy absorption rates (SAR) by calculating an electrical permittivity map of a subject. The electric permittivity is calculated by measuring the components of the B₁ field induced by a radio frequency (RF) coil (16). The Hₓ and H_{y} components of the B₁ field can be directly measured. The H_{z} component is measured by encoding it into the phase of the resonance signals. Alternately, H_{z} can be calculated by solving Gauss's law for magnetism. H_{z} can also be estimated by finding the z component of the electric field. In the specific case of a birdcage RF coil, H_{z} can be estimated by using a model of the RF coil and a subject, a model of the RF coil alone, or setting H_{z} to a constant.

### FIELD OF THE INVENTION

The present application relates to the diagnostic arts. It finds particular application in determining specific energy absorption rates in conjunction with magnetic resonance imaging, and will be described with particular reference thereto. It is to be understood, however, that the present application is more generally applicable to mapping electrical conductivity and permittivity of a patient in an MR environment, and is not necessarily limited to the aforementioned application.

### BACKGROUND OF THE INVENTION

A significant problem of imaging in a high field environment is that certain areas of a patient can absorb too much energy, causing the patient pain, discomfort, or even injury. A complex system of specific energy absorption rate (SAR) limits is taken into account to assure that patient heating does not cause tissue damage. Local SAR issues also generally prohibit scanning of patients with metallic implants (e.g. cardiac pacemakers, deep brain stimulation devices, orthopedic implants, and the like). For exact determination of local SAR, the spatial distribution of the electric field of the involved RF coil throughout the patient as well as the electric conductivity distribution throughout the patient is required.

Heretofore, reliable methods to determine the electric field and electrical conductivity accurately have proved elusive. Typically, rough estimations are performed based on global models. Uncertainties associated with such models require large safety margins, frequently leading to changes in the imaging sequence, such as an increase in repetition time that potentially could be avoided, ultimately increasing total acquisition time. Uncertainties of SAR distribution eliminates some patients from even receiving high field MRI scans.

More specifically, in order to know the SAR at a point, the electric field and the electric conductivity can be reconstructed from the knowledge of the magnetic field of the involved RF coil (B₁). This includes knowing the components of the B₁ field, commonly known as Hₓ, H_{y}, and H_{z}. Hₓ and H_{y} are relatively easy to determine. As the H_{z} component is parallel with the main magnetic field, it typically cannot be measured directly as it is indistinguishable from the main magnetic field. Therefore, to calculate SAR, H_{z} is typically estimated from the corresponding component of the electrical field, E_{z}. The resulting calculation proceeds from Ampere's law in differential form. Conductivity and permittivity are reconstructed via the curl of the magnetic field, that is, by differentiating measured B₁ maps, which is a numerically demanding task. Then the curl is divided by the E_{z}, which might be zero in some areas, leading to discontinuities.

More generally, imaging a subject's electrical properties could be clinically useful. Many applications for such mapping can be imagined, such as the ability to distinguish tumors from surrounding healthy tissue based on electrical conductivity and permittivity. It might be used to distinguish necrotic tissue from healthy tissue following a myocardial infarction. It could also be used to support the characterization of brain tissue in connection with stroke or cerebral hemorrhage. It also may be used to control outcomes in treatment of cardiac arrhythmias. Current treatments often involve catheter based ablations that change the local conductivity of the heart. Knowing the degree and extent of those changes would aid in treatment.

The present application provides a new and improved magnetic resonance imaging system which overcomes the above-referenced problems and others.

### SUMMARY OF THE INVENTION

In accordance with one aspect, a magnetic resonance system is provided. A main magnet generates a substantially uniform main magnetic field in an examination region. A radio frequency assembly induces magnetic resonance in selected dipoles of a subject in the examination region, and receives the magnetic resonance. A specific energy absorption rate calculation processor calculates a specific energy absorption rate for a region of interest from Hₓ, H_{y}, and H_{z} components of a B₁ field.

In accordance with another aspect, a method of determining a local specific energy absorption rate is provided. A substantially uniform main magnetic field is produced in a region of interest containing a subject. Magnetic resonance is induced in selected dipoles of the subject. An H_{z} component of a B₁ magnetic field is determined.

In accordance with another aspect, a magnetic resonance device is provided. A main magnet generates a substantially uniform main magnetic field in an examination region. A radio frequency assembly induces magnetic resonance in selected dipoles of a subject in the examination region, and receives the magnetic resonance. A specific energy absorption rate calculation processor calculates the specific energy absorption rate for a region of interest by measuring an Hₓ and an H_{y} component of a B₁ field, and measuring an E_{z} component of an electrical field generated by the RF assembly (16), wherein the measuring of the E_{z} component includes using the integral form of Ampere's Law:

$${∮}_{( A )} {H}_{\_}^{->} \cdot d {r}^{->} = {\int }_{A} ( {j}_{\_}^{->} + iω {D}_{\_}^{->} ) d F .$$

One advantage lies in improved SAR calculation.

Another advantage lies in the ability to image electric conductivity in vivo.

Another advantage lies in the ability to image electric permittivity in vivo.

Another advantage is the ability to image patients with metallic implants.

Still further advantages of the present invention will be appreciated to those of ordinary skill in the art upon reading and understand the following detailed description.

### BRIEF DESCRIPTION OF THE DRAWINGS

The invention may take form in various components and arrangements of components, and in various steps and arrangements of steps. The drawings are only for purposes of illustrating the preferred embodiments and are not to be construed as limiting the invention.

FIG. 1 is a diagrammatic illustration of a magnetic resonance imaging scanner in accordance with the present application;

FIG. 2 depicts possible waveforms for reading magnetic resonance with a DC current applied to the RF coil;

FIG. 3 depicts a magnetic field shift due to a DC current being applied to the RF coil;

FIG. 4 is an illustrative example of a shift with DC current applied to the RF coil;

FIG. 5 depicts possible modifications to enable an RF coil to conduct a DC current;

FIG. 6 depicts images of conductivity and SAR using various calculations of H_{z};

FIG. 7 is a depiction of a coil and patient model used to calculate H_{z} in birdcage coil.

### DETAILED DESCRIPTION OF EMBODIMENTS

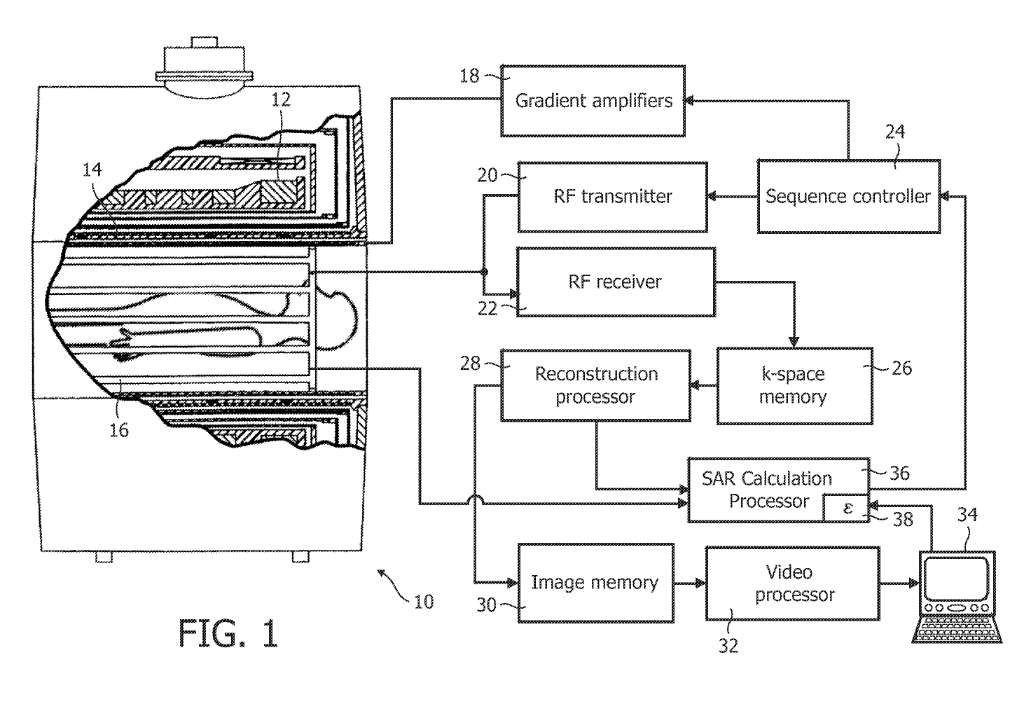

With reference to FIG. 1, a magnetic resonance scanner 10 is depicted. The magnetic resonance scanner 10 is illustrated as a closed bore system that includes a solenoidal main magnet assembly 12, although open and other magnet configurations are also contemplated. The main magnet assembly 12 produces a substantially constant main magnetic field B₀ oriented along a horizontal axis of an imaging region. It is to be understood that other magnet arrangements, such as vertical, and other configurations are also contemplated. The main magnet 12 in a bore type system may have a field strength of around 0.5 T to 7.0 T or more.

A gradient coil assembly 14 produces magnetic field gradients in the imaging region for spatially encoding the main magnetic field. Preferably, the magnetic field gradient coil assembly 14 includes coil segments configured to produce magnetic field gradient pulses in three orthogonal directions, typically longitudinal or z, trans verse or x, and vertical or y directions.

A radio frequency coil assembly 16 generates radio frequency pulses for exciting resonance in dipoles of the subject. The signals that the radio frequency coil assembly 16 transmits are commonly known as the B₁ field. The radio frequency coil assembly 16 depicted in FIG. 1 is a whole body birdcage type coil. The radio frequency coil assembly 16 also serves to detect resonance signals emanating from the imaging region. The radio frequency coil assembly 16 is a send/receive coil that images the entire imaging region, however, local send/receive coils, local dedicated receive coils, or dedicated transmit coils are also contemplated.

Gradient pulse amplifiers 18 deliver controlled electrical currents to the magnetic field gradient assembly 14 to produce selected magnetic field gradients. A radio frequency transmitter 20, preferably digital, applies radio frequency pulses or pulse packets to the radio frequency coil assembly 16 to excite selected resonance. A radio frequency receiver 22 is coupled to the coil assembly 16 or separate receive coils to receive and demodulate the induced resonance signals.

To acquire resonance imaging data of a subject, the subject is placed inside the imaging region. A sequence controller 24 communicates with the gradient amplifiers 18 and the radio frequency transmitter 20 to supplement the manipulation of spins in the region of interest. The sequence controller 24, for example, produces selected repeated echo steady-state, or other resonance sequences, spatially encodes such resonances, selectively manipulates or spoils resonances, or otherwise generates selected magnetic resonance signals characteristic of the subject. The generated resonance signals are detected by the RF coil assembly 16 or local coil (not shown), communicated to the radio frequency receiver 22, demodulated, and stored in a k-space memory 26. The imaging data is reconstructed by a reconstruction processor 28 to produce one or more image representations that are stored in an image memory 30. In one suitable embodiment, the reconstruction processor 28 performs an inverse Fourier transform reconstruction.

The resultant image representation(s) is processed by a video processor 32 and displayed on a user interface 34 equipped with a human readable display. The interface 34 is preferably a personal computer or workstation. Rather than producing a video image, the image representation can be processed by a printer driver and printed, transmitted over a computer network or the Internet, or the like. Preferably, the user interface 34 also allows a technician or other operator to communicate with the sequence controller 24 to select magnetic resonance imaging sequences, modify imaging sequences, execute imaging sequences, and so forth.

A specific energy absorption rate (SAR) processor 36 calculates SAR for portions of the subject within the imaging region. An electrical permittivity sub-processor 38 calculates the electrical permittivity e for all regions of interest, as the SAR is calculated from e. Previously, e has been found using the differential form of Ampere's law using Hₓ, H_{y}, and E_{z}. As mentioned previously, the differential form of Ampere's law has some drawbacks, such as local zeros in E_{z} leading to holes in the permittivity calculation. By using the integral form of Ampere's law, these holes can be avoided and a more robust calculation of e can be obtained, leading ultimately to a better calculation of SAR. The underlines denote a complex permittivity as explained below.

The integral form of Ampere's law is

$${∮}_{( A )} {H}_{\_}^{->} \cdot d {r}^{->} = {\int }_{A} ( {j}_{\_}^{->} + iω {D}_{\_}^{->} ) d F$$

where \vec{H} is the magnetic field, \vec{j} is the current density, \vec{D} is the displacement field, and F is the surface over which the current density is integrated. The current density \vec{j} can be replaced by

\vec{j}=σ\vec{E},

where s is the electrical conductivity and E is the electric field.

The displacement field can be replaced by

\vec{D}=ε\vec{E}.

This yields

$${∮}_{( A )} {H}_{\_}^{->} \cdot d {r}^{->} = {\int }_{A} ( ( σ + iωɛ ) {E}_{\_}^{->} ) d F ≡ {\int }_{A} \underline{ɛ} {E}_{\_}^{->} d F .$$

Now, an area A_{xy} lying in the x-y plane is chosen. Thus,

$${∮}_{( A )} {H}_{\_}^{->} \cdot d {r}^{->}$$

depends only on the components Hₓ and H_{y}, which can be easily measured for all points within the imaging region. The selection of A removes the dependence on Eₓ and E_{y} yielding

$${∮}_{( {A}_{xy} )} ( {\underline{H}}_{x} d x + {\underline{H}}_{y} d y ) = {\int }_{{A}_{xy}} \underline{ɛ} {\underline{E}}_{z} d x d y .$$

To solve for the unknown e, it is assumed that e is a constant within the area A_{xy}, yielding

$$\frac{{∮}_{( {A}_{xy} )} ( {\underline{H}}_{x} d x + {\underline{H}}_{y} d y )}{{\int }_{{A}_{xy}} {\underline{E}}_{z} d x d y} = \underline{ɛ} .$$

Since E_{z} depends on the unknown e, the iteration

$$\frac{{∮}_{( {A}_{xy} )} ( {\underline{H}}_{x} d x + {\underline{H}}_{y} d y )}{{\int }_{{A}_{xy}} {\underline{E}}_{z} ( {ɛ}^{n} ) d x d y} = {\underline{ɛ}}^{n + 1}$$

could be applied starting with, for example, literature values of e. Thus, by using Hₓ, H_{y}, and E_{z}, the permittivity sub-processor 38 finds e. Once e is known, the SAR calculation processor 36 can calculate SAR for the region.

The indicated integration is less demanding mathematically than solving the differential form of Ampere's law. Additionally, the need to divide by a zero electric field is mitigated, since no division by the electric field in limited areas is performed, rather just an integral over the electric field.

In another embodiment, the permittivity calculation sub-processor 38 uses Hₓ, H_{y}, and H_{z} to determine e instead of Hₓ, H_{y}, and E_{z}. Using H_{z} instead of E_{z} yields several advantages. One is that the computation is less mathematically intense. Another is that it allows for the accounting of anisotropic values of conductivity and permittivity. The permittivity calculation sub-processor 38 performs this calculation by performing a suitable handling of the first two Maxwell equations. Hₓ and H_{y} can be measured by well known mapping techniques of the transmit and receive sensitivity of the RF coil involved in creating the B₁ field. These sensitivities are equivalent to the two circularly polarized components of H (H⁺ and H⁻) due to

H⁺=Hₓ+iH_{y}, and

H⁻=Hₓ−iH_{y},

Ampere's law (first Maxwell equation in differential form)

∇×H(\vec{r})=iωε(\vec{e})\vec{E}(\vec{i})

and Faraday's law (second Maxwell equation in integral form)

$${\int }_{A} {H}_{\_}^{->} d F = \frac{i}{ωμ} {∮}_{( A )} {E}_{\_}^{->} \cdot d {r}^{->}$$

are used. Assuming a constant permeability μ throughout the patient, these equations yield satisfactory results. Electric conductivity s and permittivity e are summarized to the complex permittivity e=e−is/?. Dividing the first Maxwell equation by the second Maxwell equation yields

$$\frac{{∮}_{( A )} ∇ \times {H}_{\_}^{->} ( {r}^{->} ) \cdot d {r}^{->}}{{∮}_{A} {H}_{\_}^{->} d F} = {μω}^{2} \frac{{∮}_{( A )} \underline{ɛ} ( {r}^{->} ) {E}_{\_}^{->} ( {r}^{->} ) \cdot d {r}^{->}}{{∮}_{( A )} {E}_{\_}^{->} \cdot d {r}^{->}} \approx {μω}^{2} {\underline{ɛ}}^{′} ( {r}^{->} ) .$$

The obtained approximated permittivity e′ is equivalent to the actual permittivity e in regions where e is sufficiently constant, that is, where its spatial variation is significantly smaller than the spatial variation of the electric field. If this condition is not fulfilled, an iteration

$$\begin{matrix}\frac{{∮}_{( A )} \frac{{\underline{δ}}^{n} ( {r}^{->} )}{{\underline{ɛ}}^{′} ( {r}^{->} )} ∇ \times {H}_{\_}^{->} ( {r}^{->} ) \cdot d {r}^{->}}{{∮}_{A} {H}_{\_}^{->} d F} = {μω}^{2} \frac{{∮}_{( A )} \frac{{\underline{δ}}^{n} ( {r}^{->} )}{{\underline{ɛ}}^{′} ( {r}^{->} )} \underline{ɛ} ( {r}^{->} ) {E}_{\_}^{->} ( {r}^{->} ) \cdot d {r}^{->}}{{∮}_{( A )} {E}_{\_}^{->} \cdot d {r}^{->}} \\ \approx {μω}^{2} {\underline{δ}}^{n + 1} ( {r}^{->} )\end{matrix}$$

can be applied starting with d=1. The preceding two equations are the same apart from multiplying the numerator by d/e′ before taking the line integral. With this iteration, the ratio between calculated permittivity and true permittivity is identified as

$$\underline{δ} ≡ {\underline{ɛ}}^{′} / \underline{ɛ} .$$

Iteratively converging d yields the true permittivity. Finally, the SAR calculation processor 36 can use the true permittivity value (and the electric field calculated from Faraday's law) to calculate SAR using the relation

$${SAR}_{local} = {\int }_{{local }_{region}} σ ( {r}^{->} ) E ( {r}^{->} ) {E}^{*} ( {r}^{->} ) d V .$$

This calculation using H_{z} replaces the very time consuming calculation of SAR using a simulated electric field.

If e is anisotropic, such as with muscle fibers, the Maxwell equation is re-written to

∇×\vec{H}(\vec{r})=iω\hat{ε}(\vec{r})\vec{E}(\vec{r}),

which introduces the complex permittivity tensor

$${ɛ}_{\_}^{\hat{}} = ( \begin{matrix}{\underline{ɛ}}_{xx} & {\underline{ɛ}}_{xy} & {\underline{ɛ}}_{xz} \\ {\underline{ɛ}}_{yx} & {\underline{ɛ}}_{yy} & {\underline{ɛ}}_{yz} \\ {\underline{ɛ}}_{zx} & {\underline{ɛ}}_{zy} & {\underline{ɛ}}_{zz}\end{matrix} ) .$$

From the re-written Maxwell equation, the components parallel and transverse to the fiber orientation can be calculated, if the fiber orientation is extracted from anatomic images. If the fibers are approximately along a Cartesian direction, the off-diagonal tensor components cancel, and the Maxwell equation separates (j=x, y, z)

(∇×\vec{H})ⱼ=iωεⱼⱼEⱼ.

In one embodiment, a three-step approach is used to determine SAR within a patient, while remaining in compliance with local SAR regulations while doing so. First, pre-scans are performed to determine the components of the B₁ field (Hₓ, H_{y}, and H_{z}). These scans are performed at a low global SAR level to ensure compliance with SAR regulations. Secondly, the permittivity calculation sub-processor 38 calculates the permittivity map, and the SAR calculation processor 36 calculates the SAR map as described above. Lastly, diagnostic scans can be performed at elevated RF power levels using the SAR map to avoid exceeding local SAR limits.

This technique can be applied to all MR scans, and in particular scans suffering from SAR limitations. The technique can also be applied to patients with metallic implants with careful control of local SAR near these implants instead of excluding these patients from MR studies. Further, the electrical conductivity and permittivity can be imaged for medical diagnoses, such as tumor staging or stroke classification.

The above discussion is predicated on the knowledge of all three components of the B₁ field, Hₓ, H_{y}, and H_{z}. As mentioned previously, Hₓ and H_{y} are easily measured by mapping the transmit and receive sensitivity of the RF coil. H_{z} can be found in several different ways, discussed below.

One way to find H_{z} is to drive the RF coil with a DC current. By applying the DC current to the coil, it is possible to determine the spatial distribution of H_{z} per unit current of the coil B_{1z}(x)/I by encoding it into the phase of an MR image. This phase arises from the locally altered Larmor frequency due to the superposition of the coil's H_{z} with the main field. By reconstructing several images, one with no DC current applied to the RF coil, and at least one with a DC current applied, H_{z} can be determined. In one embodiment, several (e.g. 5-10) different DC values are applied to the RF coil, producing several different phase shifts. The more images with different DC values applied to the coil that are taken, the better the effect can be visualized.

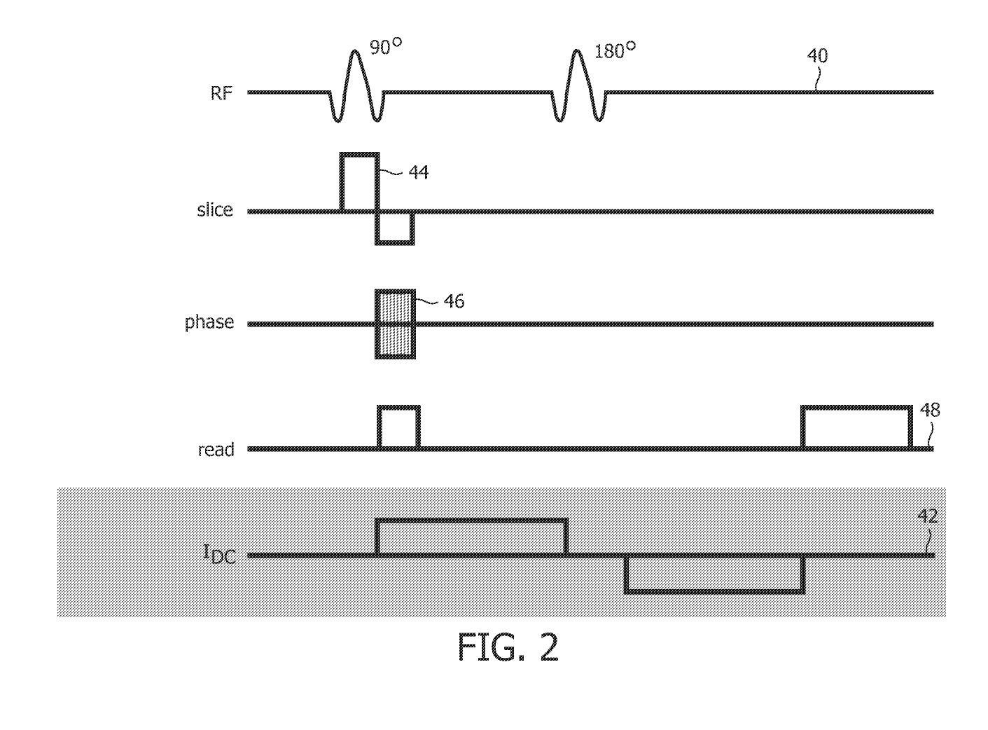

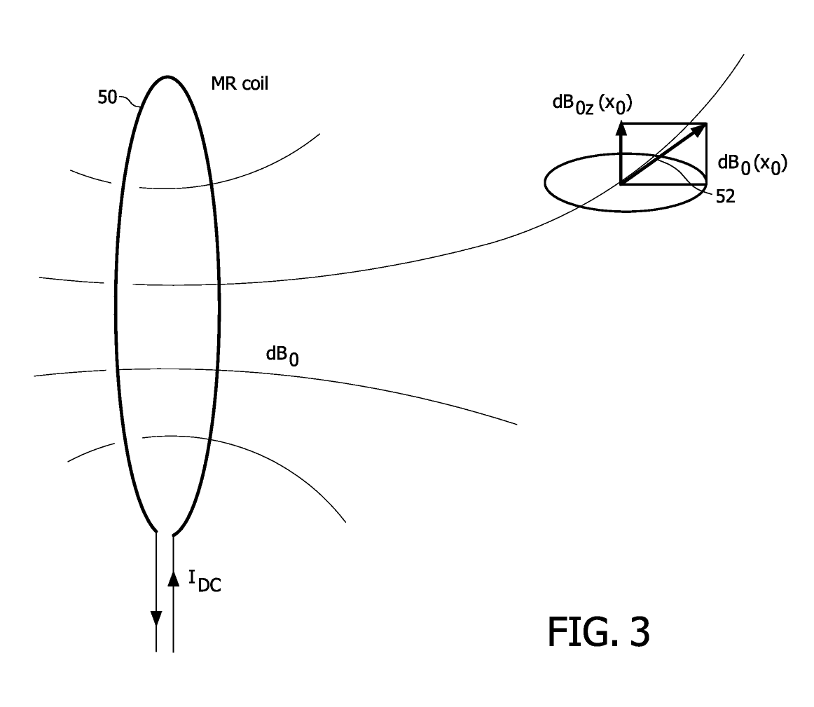

In the present embodiment, the DC current (I_{DC}) is applied to the coil for some encoding time (t_{DC}) during the phase encoding section of a spin echo image acquisition. With reference now to FIG. 2, some possible waveforms for encoding H_{z} into the phase are depicted. An RF pulse waveform 40 first tips aligned dipoles into the transverse plane and later refocuses the resonance with a 180° pulse. A DC current 42 is applied to the coil after the initial tip pulse is complete. The DC current is suspended for the refocusing pulse, and re-applied in the opposite polarity. A slice select gradient pulse 44, phase encoding gradient pulse 46, and a readout gradient waveform 48 are applied by the gradient coil 14 as is typical. In subsequent repetitions, the DC bias I_{DC} is applied with a different amplitude or duration to obtain readouts with at least two levels of DC bias. With reference now to FIG. 3, and continuing reference to FIG. 2, the applied DC current waveform 42 creates a DC magnetic field offset, dB₀(x) 50 with a spatial distribution identical to the B₁ field of a coil 50. At some location x₀, the z component of the field offset 52 will cause an additional phase in the MR image described by

φ(x₀)=γdB_{0z}(x₀)t_{DC}.

From the phase φ(x) of the image, the B₁ field distribution per unit current can be determined:

B_{1z}(x)/I=φ(x)/(γt_{DC}I_{DC}).

This measures H_{z} per unit current (H_{z}(x)/I) of an MR coil at DC. For accurate permittivity mapping, the permittivity calculation sub processor 38 requires H_{z} at the Larmor frequency. In general, the spatial sensitivity of an RF coil is frequency dependent, but for a coil size and field of view up to the effective wavelength at the Larmor frequency, the near field approximation is valid, such that the deviation from the DC case is small.

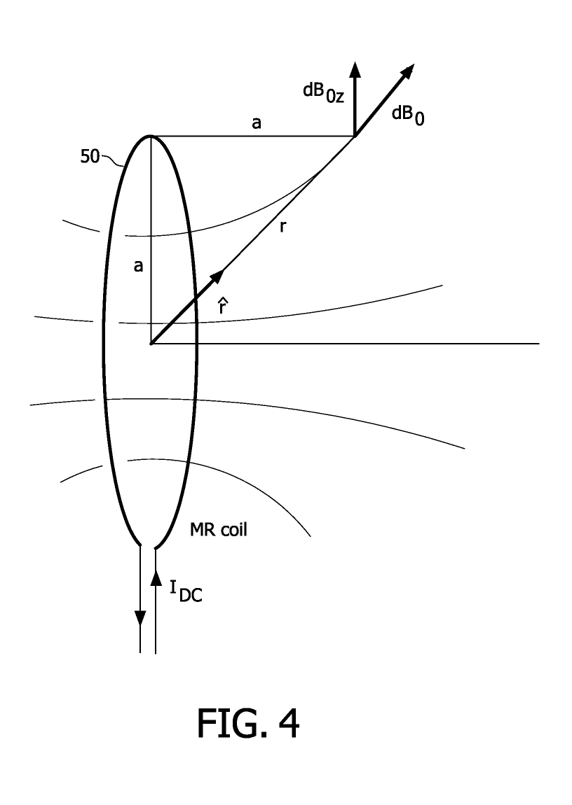

With reference now to FIG. 4, in an illustrative example, assume for a circular RF coil 50 with a radius a of 5 cm, a phase of 2 p is desired 5 cm above the coil 50 as depicted. Assume also that the particular sequence allows for an encoding time t_{DC} of 100 ms. This would require a local z component dB₀, of 0.235 μT, which corresponds to a local magnitude dB₀ of 0.333 μT due to a geometry factor of roughly v2, as seen in FIG. 4. The field of a dipole loop expressed in circular coordinates is

$${B}^{->} = \frac{{μ}_{0} {a}^{2} {I}_{DC}}{4 {r}^{3}} ( 2 cos θ \hat{r} + sin θ \hat{θ} )$$

where the z-direction is perpendicular to the loop. From the geometry of FIG. 4, it follows that the local dB₀ points approximately in the direction of the radial unit vector. With r=av2 and ?=45°

$$d {B}_{0} = \frac{{μ}_{0} π {a}^{2} {I}_{DC}}{4 {( a \sqrt{2} )}^{3}} 2 cos 45 ° = \frac{{μ}_{0} {I}_{DC}}{8 a} .$$

Solving this equation for I_{DC} yields I_{DC}=106 mA, which is applicable in practice. Working in reverse, by knowing the DC current applied to the coil, and by observing the resulting phase shift at points with known geometry relative to the coil, the z component of the B₁ field, H_{z}, can be calculated.

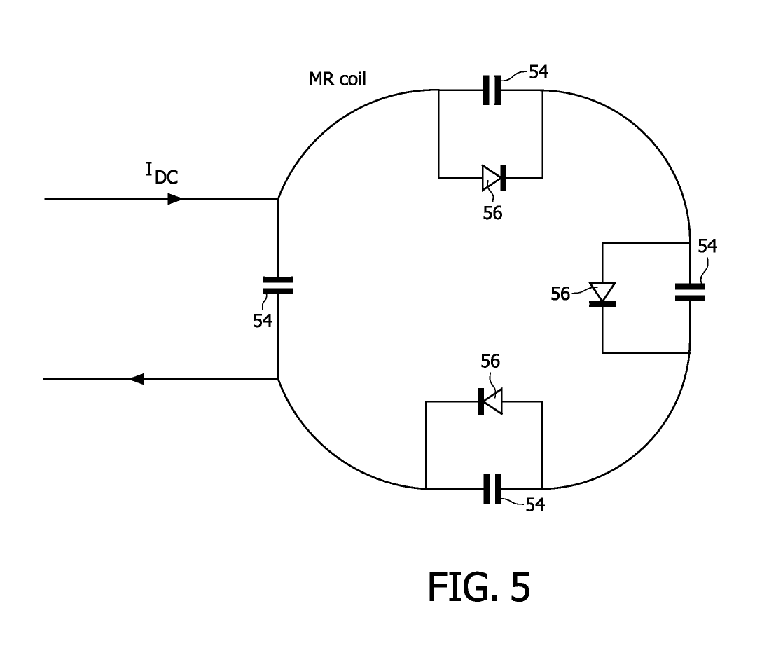

Normally, RF coils are driven with an AC signal. With reference now to FIG. 5, possible modifications to a typical RF coil 50 to enable the coil to be driven with a DC current are provided. Typically, RF coils include distributed capacitors 54 to avoid local extremes in the electrical field of the coil at its extremities. These capacitors 54 would normally block a DC current. In the illustrated embodiment, diodes 56 are placed in parallel with the capacitors to allow a path for the DC current. Diodes with a capacitance of about 1 pF that can take forward currents up to 250 mA are suitable to create a DC current path in the coil 50. Using a separate coil has also been contemplated, provided it had the exact same send/receive characteristics as the RF coil 50.

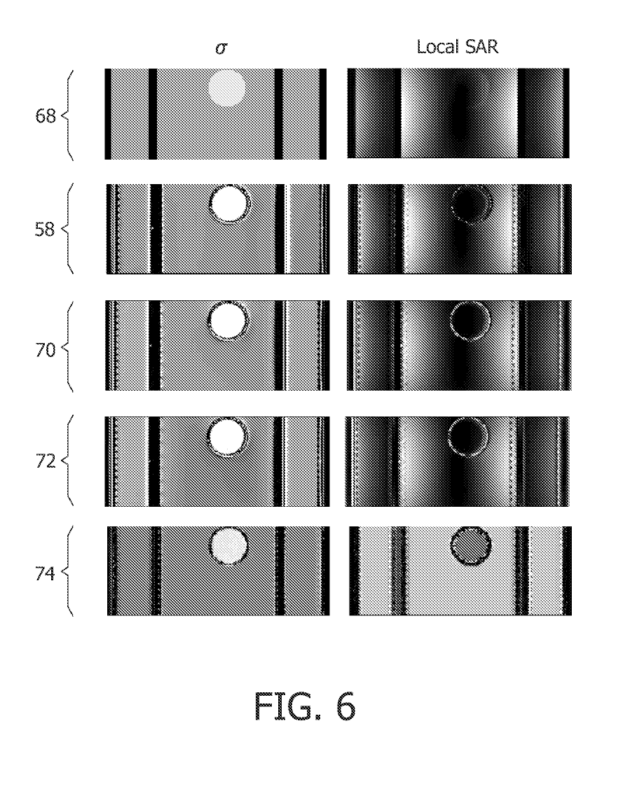

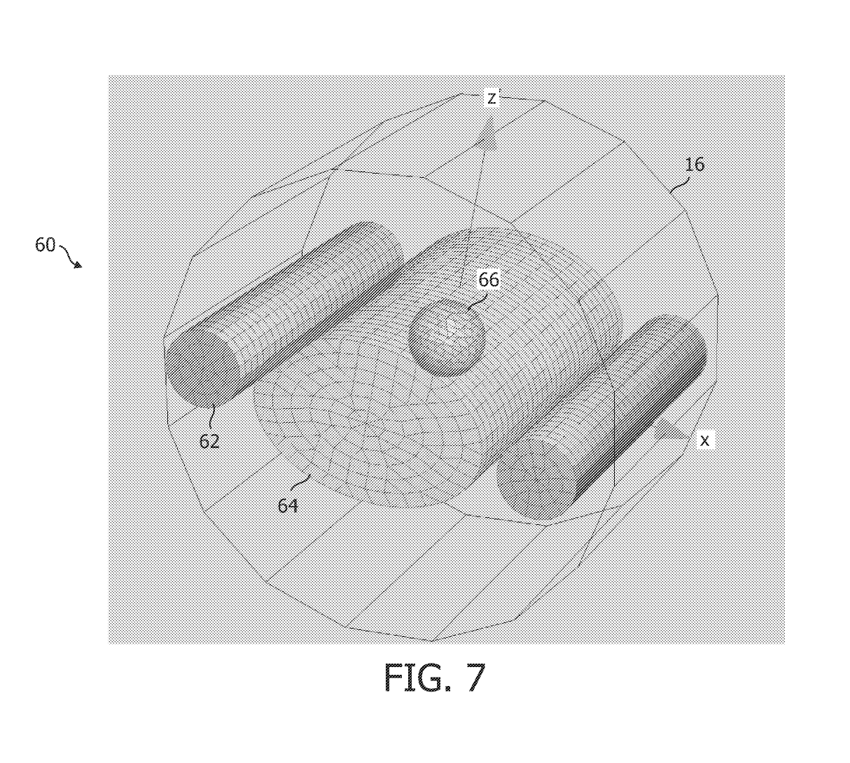

In the embodiment of FIG. 1, the radio frequency assembly 16 includes a full body birdcage coil. For the special case of a birdcage coil, the geometry of the coil allows H_{z} to be adequately estimated. First, H_{z} can be estimated using a full model of the coil and patient. This method of estimation is the most complete, and is only susceptible to model errors and numerical errors (e.g., imperfect differentiation). With reference now to FIG. 6, the results of using a full model of a subject and coil 58 in estimating H_{z} are depicted. The model used 60 is shown in FIG. 7. The birdcage coil 16 depicted has a diameter of 60 cm. The conductivity of the arms 62 and thorax 64 is s=0.5 S/m. The conductivity for the spherical body 66 located in the thorax is s=1 S/m. The relative permittivity of the arms 62 and thorax 64 is eᵣ=81, and for the body 66 eᵣ=40. Coronal slices of the subject model were taken. The left column represents the calculated electrical conductivity s, while the right column represents calculated local SAR. Using the subject and coil model, the results 58 are 99.7% in correlation with true conceptual SAR 68. Only errors from the numerical differentiation/integration along the compartment boundaries are visible.

Another method of estimation models the used RF coil only. The results of this method 70 are 98.8% in correlation with true SAR 68. This method introduces a systematic error, but is easier to implement than the full model. The systematic error is negligible in the case of birdcage coils, as it can hardly be recognized by visual inspection.

Another method of estimating H_{z} for a birdcage coil is to assume that H_{z} is a constant. This is the easiest method to implement, but it increases the systematic error. Results of this method 72 are 96.8% in correlation with true SAR 68. This error is acceptable in the case of birdcage coils, as it does not lead to significant changes in the reconstructed SAR. The same holds true for the underlying conductivity.

For a birdcage coil, permittivity can be approximated using

$$\frac{{∮}_{( A )} ∇ \times {H}_{\_}^{->} ( {r}^{->} ) \cdot d {r}^{->}}{{μω}^{2} {\int }_{A} {H}_{\_}^{->} d F} \approx \underline{ɛ} ( {r}^{->} )$$

When using an approximated H_{z} it is important to distinguish between transverse and non-transverse slices. For transverse slices, the integration area is in the x-y plane A=A_{xy}, and the above equation changes to read

$$\frac{{∮}_{( {A}_{xy} )} \{ ( {\partial }_{y} {\underline{H}}_{z} - {\partial }_{z} {\underline{H}}_{y} ) , ( {\partial }_{z} {\underline{H}}_{x} - {\partial }_{x} {\underline{H}}_{z} ) \} \cdot d {r}^{->}}{{μω}^{2} {\int }_{{A}_{xy}} {\underline{H}}_{z} d {F}_{xy}} \approx \underline{ɛ} ( {r}^{->} ) .$$

For a coronal slice, the integration area is in the x-z plane A=A_{xz}, and it would then read

$$\frac{{∮}_{( {A}_{xz} )} \{ ( {\partial }_{y} {\underline{H}}_{z} - {\partial }_{z} {\underline{H}}_{y} ) , ( {\partial }_{x} {\underline{H}}_{y} - {\partial }_{y} {\underline{H}}_{x} ) \} \cdot d {r}^{->}}{{μω}^{2} {\int }_{{A}_{xz}} {\underline{H}}_{y} d {F}_{xz}} \approx \underline{ɛ} ( {r}^{->} ) .$$

Sagittal slices are not considered, since the influence of an approximated H_{z} is the same for coronal and sagittal slices. A comparison of the previous two equations suggests that transverse planes are more affected by simplifications of H_{z} since H_{z} appears twice in the numerator and is the only input for the denominator. For non-transverse slices, H_{z} appears only once in the numerator, but not in the denominator at all. While conductivity and permittivity are assumed to be isotropic for the results of FIG. 6, if these values are anisotropic, they can be accounted for by using the complex permittivity tensor, as discussed previously.

In another embodiment, Gauss's law for magnetism with no magnetic monopoles is used to estimate H_{z}. In this embodiment, no models are needed, and it can be used in conjunction with any RF coil, that is, it is not necessarily limited to birdcage coils. Gauss's law for magnetism is given by

$$∇ \cdot H = \frac{\partial {H}_{x}}{\partial x} + \frac{\partial {H}_{y}}{\partial y} + \frac{\partial {H}_{z}}{\partial z} = 0.$$

Solving for H_{z}, the equation yields

$${H}_{z} = {\int }_{a}^{b} ( - \frac{\partial {H}_{x}}{\partial x} - \frac{\partial {H}_{y}}{\partial y} ) d z .$$

As noted earlier, Hₓ and H_{y} can be easily measured, so are known values for the purposes of this calculation. The only variable is that the integral boundaries remain free parameters, but can be adequately estimated by assuming that H_{z} is zero along a line through the isocenter in each slice of a 3D volume. Referring again to FIG. 6, results of this embodiment 74 yield a 99% correlation with conceptual conductivity, and a 90% correlation with conceptual local SAR, shown at 68.

In yet another embodiment, H_{z} can be taken from a B₀ map, which is usually measured by a dual or multi-echo sequence. The B₀ map shows changes in H_{z} due to susceptibility artifacts. This H_{z} can be used as an additive correction for an H_{z} determined via any of the above-described methods.

The described formalism yields a quantitative value of e without knowledge of the absolute scaling of the magnetic field of the RF coil involved. However, standard methods of scaling the transmitted B₁ field can be used to determine absolute values for the electric field calculated via Faraday's law, and thus, absolute values for the derived local SAR.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof.

1. A magnetic resonance system comprising:
a main magnet (12) for generating a substantially uniform main magnetic field in an examination region;
a radio frequency assembly (16) for inducing magnetic resonance in selected dipoles of a subject in the examination region, and receiving the magnetic resonance;
a specific energy absorption rate calculation processor (36) that calculates a specific energy absorption rate for a region of interest from Hₓ, H_{y}, and H_{z} components of a B₁ field.

2. The magnetic resonance system as set forth in claim 1, wherein the specific energy absorption rate calculation processor (36) includes an electrical permittivity sub-processor (38) that determines an electrical permittivity value for the at least one region of interest from Hₓ, H_{y}, and H_{z}.

3. The magnetic resonance system as set forth in claim 2, wherein the H_{z} component of the B₁ field is measured by electrical permittivity sub-processor (38) to determine the electrical permittivity of the at least one region of interest, wherein H_{z} is observed by encoding it into the signal phase.

4. The magnetic resonance system as set forth in claim 3, wherein a sequence controller (24) is configured to encode H_{z} into the signal phase by driving the radio frequency coil assembly (16) with a DC current.

5. The magnetic resonance system as set forth in claim 2, wherein the radio frequency assembly (16) includes a birdcage coil and the H_{z} component of the B₁ field is estimated by the electrical permittivity sub-processor (38) to determine the electrical permittivity of the at least one region of interest, wherein H_{z} is estimated by using at least one of a patient phantom and the birdcage coil.

6. The magnetic resonance system as set forth in claim 2, wherein the H_{z} component of the B₁ field is calculated by the electrical permittivity sub-processor (38) to determine the electrical permittivity of the at least one region of interest, wherein H_{z} is calculated by the relationship:
$${H}_{z} = {\int }_{a}^{b} ( - \frac{\partial {H}_{x}}{\partial x} - \frac{\partial {H}_{y}}{\partial y} ) d z$$
where Hₓ and H_{y} are measured.

7. The magnetic resonance system as set forth in claim 1, wherein the radio frequency assembly (16) includes at least one radio frequency coil selectively driven by a DC current, the radio frequency coil including capacitances and diodes in parallel with the capacitances, the diodes enabling a DC current to drive the coil.

8. A method of determining local specific energy absorption rate comprising:
producing a substantially uniform main magnetic field in a region of interest containing a subject;
inducing magnetic resonance in selected dipoles of the subject;
determining an H_{z} component of a B₁ magnetic field.

9. The method as set forth in claim 8, further including:
calculating an electrical permittivity from the determined value of H_{z}.

10. The method as set forth in claim 9 further including:
calculating a specific energy absorption rate from the calculated electrical permittivity.

11. The method as set forth in claim 8, further including:
calculating an electrical conductivity from the determined value of H_{z}.

12. The method as set forth in claim 8, wherein H_{z} is calculated by encoding it into a phase of the induced resonance.

13. The method as set forth in claim 12, wherein H_{z} is encoded into the phase of the induced resonance by driving a radio frequency coil (16, 50) with a DC signal.

14. The method as set forth in claim 8, wherein the magnetic resonance is induced by a birdcage coil (16), and H_{z} is calculated by estimation based on at least one of a model of the birdcage coil (16) and a model of a subject (62, 64, 66).

15. The method as set forth in claim 8, further including:
measuring Hₓ and H_{y} components of the B₁ field and wherein H_{z} is calculated by using the relation
$${H}_{z} = {\int }_{a}^{b} ( - \frac{\partial {H}_{x}}{\partial x} - \frac{\partial {H}_{y}}{\partial y} ) d z .$$
